(19) United States
(12) Patent Application Publication
(10) Pub. No.: US 2026/0251936 A1
(43) Pub. Date: Aug. 27, 2026

(54) Reflective structure and backlight module

(71) Applicant: Coretronic Corporation, Hsin-Chu (TW)

(72) Inventors: SHIH-YEN CHENG, Hsin-Chu (TW); CHUN-WEI LEE, Hsin-Chu (TW); SHIH-HSIUNG TSENG, Hsin-Chu (TW); YI-HSUN LEE, Hsin-Chu (TW)

(21) Appl. No.: 19/531,708

(22) Filed: Feb. 6, 2026

(30) Foreign Application Priority Data
Feb. 26, 2025 (TW) 114201973

(51) Int. Cl. G02F 1/13357

(52) U.S. Cl. CPC G02F 1/133605

(57) ABSTRACT

A reflective structure includes a main body. The main body has a plurality of light source accommodating cavities and a plurality of reflective walls. The reflective walls respectively surround the light source accommodating cavities, wherein the reflective walls include a plurality of segmented walls, and each of the segmented walls has a first wall portion and a second wall portion separated from each other. The main body is divided into a first portion and a second portion separated from each other via the segmented walls. A backlight module having the reflective structure is also provided.

### CROSS-REFERENCE TO RELATED APPLICATION

This application claims priority to Taiwan Application No. 114201973, filed on Feb. 26, 2025. The entirety of the above-mentioned patent application is hereby incorporated by reference herein and made a part of this specification.

### TECHNICAL FIELD

The disclosure relates to an optical structure, and more particularly to a reflective structure and a backlight module including the same.

### BACKGROUND

The structure of a liquid crystal display mainly includes components, such as a backlight module, a display panel, and an outer frame. Based on the orientation of the light source, the backlight module can be categorized into an edge-type backlight module and a direct-type backlight module. The direct-type backlight module offers better uniformity of the area light source and facilitates the implementation of local dimming functionality. Accordingly, LCDs employing direct-type backlight modules typically exhibit enhanced image contrast. Currently, most medium- to large-sized LCDs utilizing light-emitting diodes (LEDs) as the light source adopt direct-type backlight modules.

The information disclosed in this “BACKGROUND” section is only for enhancement understanding of the background and therefore it may contain information that does not form the prior art that is already known to a person of ordinary skill in the art. Furthermore, the information disclosed in this “BACKGROUND” section does not mean that one or more problems to be solved by one or more embodiments of the disclosure were acknowledged by a person of ordinary skill in the art.

### SUMMARY

The disclosure provides a reflective structure for reducing dimensional variation when the environmental temperature increases.

The disclosure provides a backlight module for enhancing durability.

Other advantages and objects of the disclosure may be further illustrated by the technical features broadly embodied and described as follows.

In order to achieve one, parts, or all of the above objects or other objects, an embodiment of the disclosure provides a reflective structure including a main body. The main body includes a plurality of light source accommodating cavities and a plurality of reflective walls surrounding the light source accommodating cavities, respectively. The plurality of reflective walls include a plurality of segmented walls. Each of the segmented walls includes a first wall portion and a second wall portion separated from each other. The main body is divided into a first portion and a second portion by the segmented walls.

To achieve one, some, or all of the above-mentioned objectives, or other objectives, the disclosure provides a backlight unit including a substrate, a plurality of light emitting elements, and a reflective structure. The plurality of light emitting elements are disposed on a surface of the substrate. The reflective structure is disposed on the surface of the substrate. The plurality of light emitting elements are disposed within light source accommodating cavities of the reflective structure.

Other objectives, features, and advantages of the present disclosure will be further understood from the further technological features disclosed by the embodiments of the present disclosure wherein there are shown and described preferred embodiments of this disclosure, simply by way of illustration of modes best suited to carry out the disclosure.

### BRIEF DESCRIPTION OF THE DRAWINGS

The accompanying drawings are included to provide a further understanding of the disclosure and are incorporated in and constitute a part of this specification. The drawings illustrate embodiments of the disclosure and, together with the description, serve to explain the principles of the disclosure.

FIG. 1 is a schematic top view of a backlight module according to one embodiment of the disclosure;

FIG. 2 is a partial cross-sectional view of the backlight module, taken along line A0-A0 in FIG. 1;

FIG. 3 is a schematic cross-sectional view of the reflective structure before and after volumetric expansion, taken along line A1-A1 in FIG. 1;

FIG. 4 is a schematic top view of a backlight module according to another embodiment of the disclosure;

FIG. 5 is a schematic perspective view of a backlight module according to another embodiment of the disclosure;

FIG. 6 is a schematic cross-sectional view of the backlight module, taken along line A2-A2 in FIG. 5;

FIG. 7 is a schematic perspective view of a backlight module according to another embodiment of the disclosure;

FIG. 8 is a schematic perspective view of the backlight module of FIG. 7 with the reflective sheets omitted;

FIG. 9 is a schematic cross-sectional view of the backlight module, taken along line A3-A3 in FIG. 7;

FIG. 10 is a schematic top view of the backlight module of FIG. 7;

FIG. 11 is a schematic perspective view of a backlight module according to another embodiment of the disclosure;

FIG. 12 is a schematic perspective view of the backlight module of FIG. 11 with the reflective sheets omitted;

FIG. 13 is a schematic cross-sectional view of the backlight module, taken along line A4-A4 in FIG. 11;

FIG. 14 is a schematic top view of the backlight module according to another embodiment of the disclosure;

FIG. 15 is a schematic top view of the backlight module according to another embodiment of the disclosure;

FIG. 16 is a schematic top view of the backlight module according to another embodiment of the disclosure;

FIG. 17 is a schematic top view of the backlight module according to another embodiment of the disclosure; and

FIG. 18 is a schematic top view of the backlight module according to another embodiment of the disclosure.

### DETAILED DESCRIPTION OF PREFERRED EMBODIMENTS

In the following detailed description of the preferred embodiments, reference is made to the accompanying drawings which form a part hereof, and in which is shown by way of illustration specific embodiments in which the disclosure may be practiced. In this regard, directional terminology, such as “top”, “bottom”, “front”, “back”, etc., is used with reference to the orientation of the Figure(s) being described. The components of the disclosure can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the disclosure. Also, it is to be understood that the phraseology and terminology used herein are for the purpose of description and should not be regarded as limiting. The use of “including”, “comprising”, or “having” and variations thereof herein is meant to encompass the items listed thereafter and equivalents thereof as well as additional items. Unless limited otherwise, the terms “connected”, “coupled”, and “mounted” and variations thereof herein are used broadly and encompass direct and indirect connections, couplings, and mountings. Similarly, the terms “facing”, “faces”, and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component facing “B” component directly or one or more additional components is between “A” component and “B” component. Also, the description of “A” component “adjacent to” “B” component herein may contain the situations that “A” component is directly “adjacent to” “B” component or one or more additional components is between “A” component and “B” component. Unless limited otherwise, the terms “connected,” “coupled,” and “mounted,” and variations thereof herein are used broadly and encompass direct and indirect connections, couplings, and mountings. Accordingly, the drawings and descriptions will be regarded as illustrative in nature and not as restrictive.

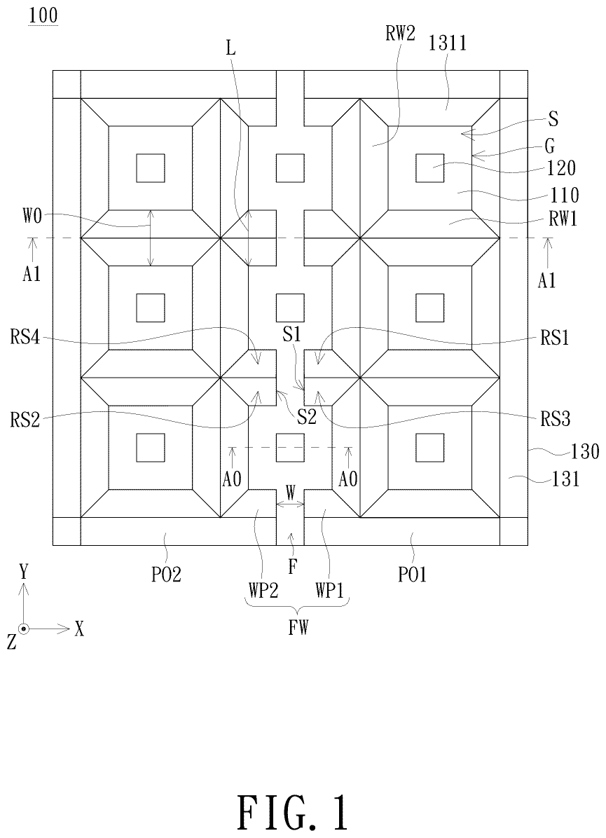

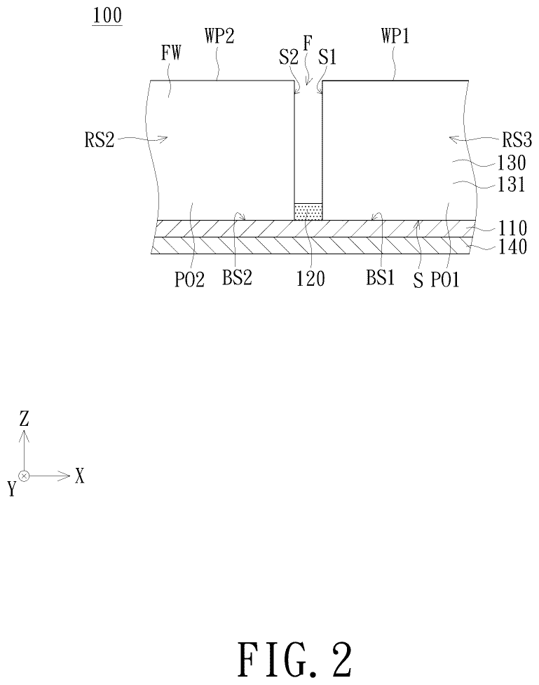

FIG. 1 is a schematic top view of a backlight module according to one embodiment of the disclosure. FIG. 2 is a partial cross-sectional view of the backlight module, taken along line A0-A0 in FIG. 1. Please refer to FIG. 1 and FIG. 2. A backlight module 100 includes a substrate 110, a plurality of light emitting elements 120, and a reflective structure 130. The light emitting elements 120 are disposed on a surface S of the substrate 110. The reflective structure 130 is disposed on the surface S. The reflective structure 130 includes a main body 131. The main body 131 includes a plurality of light source accommodating cavities G and a plurality of reflective walls 1311. The reflective walls 1311 surround the light source accommodating cavities G, respectively. The light emitting elements 120 are disposed in the light source accommodating cavities G, respectively. The reflective walls 1311 include a plurality of segmented walls FW. Each of the segmented walls FW includes a first wall portion WP1 and a second wall portion WP2 separated from each other. The first wall portion WP1 and the second wall portion WP2 separated from each other collectively form a gap F at a location of the segmented wall FW. In other words, the gap F is located between the first wall portion WP1 and the second wall portion WP2, and the first wall portion WP1 and the second wall portion WP2 are separated from each other by the gap F. The main body 131 is divided into a first portion PO1 and a second portion PO2 by the gaps F of the segmented walls FW.

The substrate 110 includes a circuit board, for example. The circuit board includes a printed circuit board. However, the disclosure is not limited thereto.

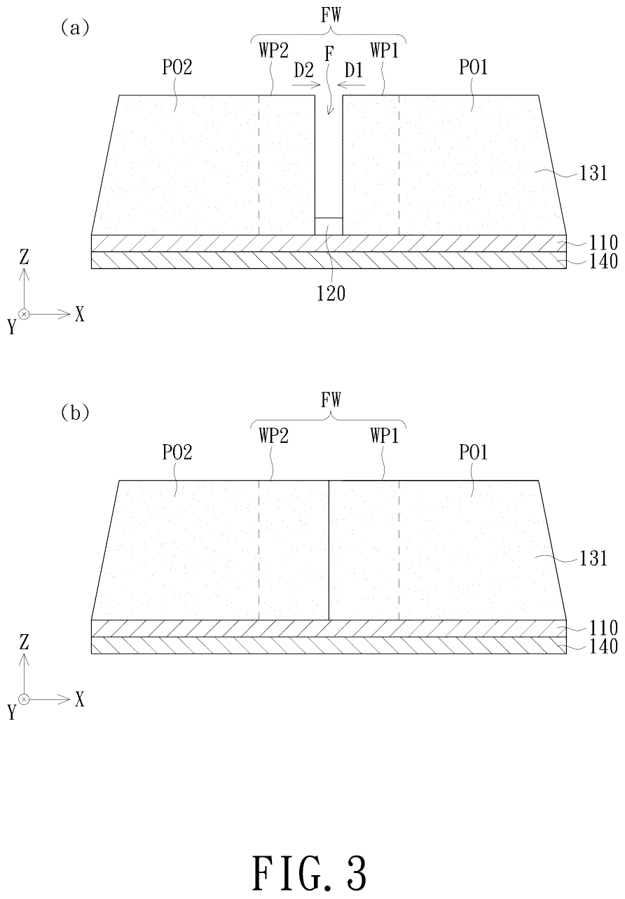

FIG. 3 is a schematic cross-sectional view of the reflective structure before and after volume expansion, taken along line A1-A1 in FIG. 1. Specifically, FIG. 3(a) shows the main body 131 under the room temperature, and FIG. 3(b) shows the volume expansion of the main body 131 after the temperature rises. As shown in FIG. 1 and FIG. 3, in the embodiment, the main body 131 of the reflective structure 130 can adopt a material with a coefficient of thermal expansion different from that of the substrate 110. For example, the main body 131 may include polycarbonate (PC) where the coefficient of thermal expansion of PC is greater than that of the substrate 110. Since the main body 131 is fixed onto the substrate 110, the amount of volumetric thermal expansion of the main body 131 will be greater than that of the substrate 110 when the ambient temperature surrounding the backlight module 100 increases. Furthermore, when the volumes of first portion PO1 and the second portion PO2 expand, each of the first wall portions WP1 may expand in the direction D1 and each of the second wall portions WP2 may expand in the direction D2, thereby preventing excessive outward expansion of the main body 131. Accordingly, the expansion volumes of the first portion PO1 and the second portion PO2 are absorbed by the gap F, thereby reducing the dimensional changes of the main body 131 and preventing the main body 131 from causing deformation of the substrate 110 due to significant dimensional increase.

On the other hand, the backlight module 100 can further include a back plate 140 (illustrated in FIG. 2) fixed on one side of the substrate 110 facing away from the reflective structure 130. Similarly, the coefficient of thermal expansion of the main body 131 is greater than that of the back plate 140. Thus, the difference of the dimensional changes between the main body 131 and the back plate 140 after the ambient temperature rises can be reduced effectively, thereby preventing the main body 131 from causing deformation of the back plate 140 due to significant dimensional increase.

Please refer to FIG. 1 and FIG. 2. In the embodiment, the reflective walls 1311 further include a plurality of first reflective walls RW1 and a plurality of second reflective walls RW2. The first reflective walls RW1 are connected to each other and extend along a first direction X. The second reflective walls RW2 are connected to each other and extend along a second direction Y which is different to the first direction X. More than one of the first reflective walls RW1 include the segmented walls FW, or more than one of the second reflective walls RW2 include the segmented walls FW. Thus, the volumetric expansion along the first direction X or the second direction Y can be absorbed by the segmented walls FW, thereby reducing the dimensional change of the reflective structure 130 in the first direction X or the second direction Y.

For example, in the embodiment, four of the first reflective walls RW1 are segmented walls FW and none of the second reflective walls RW2 is a segmented wall. The four segmented walls FW can be located in the same row so as to divide the main body 131 into the first portion PO1 and the second portion PO2, thereby absorbing the volumetric expansion of the main body 131 in the first direction X. In an embodiment not illustrated, none of the first reflective walls RW1 includes the segmented wall FW and at least a portion of the second reflective walls RW2 include the segmented walls FW. All of the segmented walls FW are located in the same column (e.g., arranged along the first direction X) so as to divide the main body 131 into the first portion PO1 and the second portion PO2, thereby absorbing the volumetric expansion of the main body 131 in the second direction Y. In the embodiment, the first direction X and the second direction Y, for example, are substantially perpendicular to each other, such that the first reflective walls RW1 and the second reflective walls RW2 are arranged in an intersecting manner to form a grid pattern, thereby defining the light source accommodating cavities G arranged in an array.

In each of the segmented walls FW according to the embodiment, the first wall portion WP1 includes a first cut surface S1, a first reflective surface RS1, and a first bottom surface BS1. The first cut surface S1 and the first reflective surface RS1 are connected to each other and stand on the first bottom surface BS1. The first cut surface S1 faces the adjacent second wall portion WP2. In each of the segmented walls FW, the second wall portion WP2 includes, for example, a second cut surface S2, a second reflective surface RS2, and a second bottom surface BS2. The second cut surface S2 faces the first cut surface S1 (i.e., facing the adjacent first wall portion WP1) and stands on the second bottom surface BS2. The second reflective surface RS2 is connected to the second cut surface S2 and stands on the second bottom surface BS2. In each of the segmented walls FW, the first reflective surface RS1 is disposed on one side of each of the segmented walls FW, and the second reflective surface RS2 is disposed on another side opposite to the one side of the segmented wall FW. For example, the first reflective surface RS1 and the second reflective surface RS2 face two different directions respectively, wherein the first reflective surface RS1 may face a direction between the second direction Y and a direction Z in the YZ-plane, and the second reflective surface RS2 may face a direction between a direction-Y (i.e., opposite to the second direction Y) and the direction Z in the YZ-plane. In addition, the first reflective surface RS1 and the second reflective surface RS2 may be located in the two adjacent light source accommodating cavities G, respectively. Each of the gaps F is located between the first reflective surface RS1 and the second reflective surface RS2 facing each other.

In addition, each of the first wall portions WP1 may further include a third reflective surface RS3 opposite to the first reflective surface RS1, and each of the second wall portions WP2 may further include a fourth reflective surface RS4 opposite to the second reflective surface RS2. Furthermore, the first wall portions WP1 and the second wall portions WP2 may be shaped as triangular prisms, and the first cut surface S1 and the second cut surface S2 may be the end surfaces of the triangular prisms respectively. The first reflective surface RS1, the third reflective surface RS3, and the first bottom surface BS1 are connected to the first cut surface S1, and the second reflective surface RS2, the fourth reflective surface RS4, and the second bottom surface BS2 are connected to the second cut surface S2. In the embodiment, the first bottom surface BS1 and the second bottom surface BS2 may be substantially parallel to the XY-plane, the first reflective surface RS1 and the third reflective surface RS3 may be inclined relative to the first bottom surface BS1, and the second reflective surface RS2 and the fourth reflective surface RS4 may be inclined relative to the second bottom surface BS2. The first reflective surface RS1 and the fourth reflective surface RS4 may face the same direction (a direction located on the YZ-plane and between the second direction Y and the direction Z in FIG. 1) and be located within the same light source accommodating cavity G. Similarly, the second reflective surface RS2 and the third reflective surface RS3 may face the same direction (a direction located on the YZ-plane and between the direction −Y and the direction Z) and be located within the same light source accommodating cavity G. Moreover, the first cut surface S1 and the second cut surface S2 may be configured to reflect light beams. For example, the main body 131 may be monolithically formed from a reflective material. As a result, all the surfaces of the first wall portions WP1 and the second wall portions WP2 are capable of reflecting light beams.

Each of the first cut surfaces S1 may be substantially perpendicular to each of the first reflective surfaces RS1, and each of the second cut surfaces S2 may be substantially perpendicular to each of the second reflective surfaces RS2. Accordingly, a length L of the gap F can be reduced, thereby facilitating the manufacturing process of the gap F. In the embodiment, the gap F may be arranged along the second direction Y to cut through the first reflective wall RW1, and the length L of the gap F is approximately equal to a width W0 of the first reflective wall RW1 in the second direction Y. In an embodiment, an angle between the first cut surface S1 and the first reflective surface RS1 may be approximately between 85 and 95 degrees, and an angle between the second cut surface S2 and the second reflective surface RS2 may be approximately between 85 and 95 degrees. Moreover, the gap F in the embodiment is formed by cuting the reflective wall 1311. In one embodiment, the main body 131 having the gaps F can be formed monolithically.

In the embodiment, in each of the segmented walls FW, the first cut surface S1 may be substantially parallel to the second cut surface S2. For example, the first cut surface S1 and the second cut surface S2 may be substantially parallel to the YZ-plane. Thus, the gap F may remain a constant width in the first direction X. In other words, a spacing between the first cut surface S1 and the second cut surface S2 along the first direction X can remain the same. Accordingly, even if the first cut surface S1 and/or the second cut surface S2 is non-planar, for example, having a curved surface, a jagged surface, or the like, the spacing between the first cut surface S1 and the second cut surface S2 at different corresponding positions remains substantially constant, thereby preserving sufficient room for volumetric expansion of the first wall portion WP1 and the second wall portion WP2. As such, it further helps to prevent the first wall portion WP1 and the second wall portion WP2 from contacting each other due to thermal expansion. In one embodiment, an angle between the first cut surface S1 and the second cut surface S2 may be approximately between −5 and 5 degrees. However, the disclosure is not limited thereto. Also, in the embodiment, the width W of the gap F may be determined according to factors such as the material or size of the main body 131. For example, in one embodiment, the width W of the gap F may be approximately between 0.5 mm and 1.5 mm. However, other embodiments are not limited thereto.

In the embodiment, the light emitting elements 120 may be arranged in an array on the surface S of the substrate 110. The light emitting elements 120 may be first fixed on the surface S of the substrate 110 and electrically connected to the substrate 110. The reflective structure 130 may be aligned with the light emitting elements 120 via the light source accommodating cavities G and be fixed on the surface S of the substrate 110. The light emitting elements 120 may include, for example, light emitting diodes. However, the disclosure is not limited thereto.

In comparison with the prior art, in the embodiment, the main body 131 of the reflective structure 130 includes a plurality of reflective walls 1311. The reflective walls 1311 include a plurality of segmented walls FW. By using the gaps F of the segmented walls FW, the main body 131 is divided into a first portion PO1 and a second portion PO2 separated from each other. In this manner, when the ambient temperature rises, the first portion PO1 and the second portion PO2 separated from each other may absorb the volumetric expansion of the main body 131, thereby preventing significant dimensional changes of the main body 131 due to the ambient temperature increase. Based on the foregoing, the embodiment is capable of reducing dimensional changes of the reflective structure 130 when the ambient temperature increases. Since the backlight module 100 of the embodiment adopts the reflective structure 130, when the temperature rises, the difference in dimensional changes between the reflective structure 130 and other components (e.g., the substrate 110 and the back plate 140) can be reduced, thereby preventing deformation of the backlight module 100 caused by excessive differences in dimensional changes. Accordingly, the embodiment improves the durability of the backlight module 100.

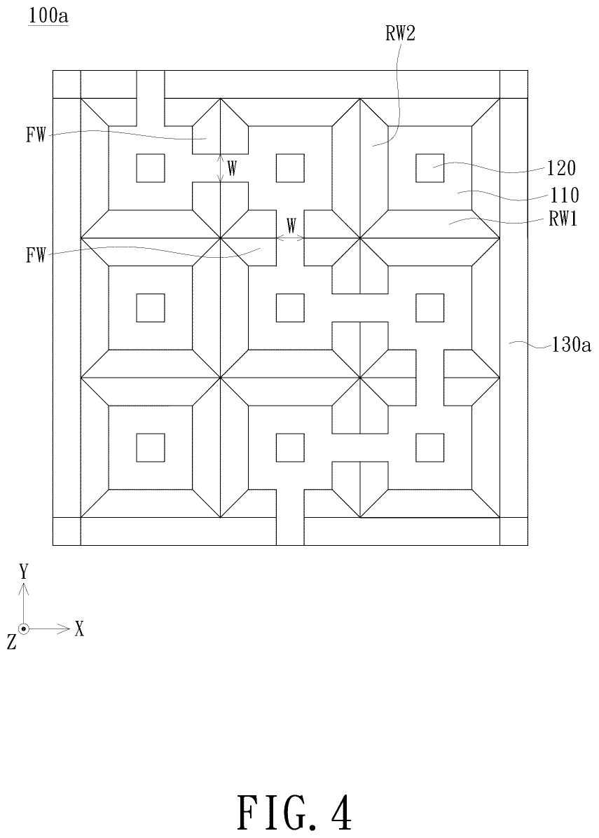

FIG. 4 is a schematic top view of a backlight module according to another embodiment of the disclosure. The structures and advantages of the backlight module 100a and the reflective structure 130a in the embodiment are similar to those of the embodiment shown in FIG. 1, and only the differences will be described below. Please refer to FIG. 4. At least one of the first reflective walls RW1 includes the segmented wall FW, and at least one of the second reflective walls RW2 includes the segmented wall FW. Accordingly, these segmented walls FW are capable of absorbing the volumetric expansion of the reflective structure 130a in the first direction X and in the second direction Y, thereby reducing the dimensional changes of the reflective structure 130a in the first direction X and in the second direction Y. Specifically, in the embodiment, four of the first reflective walls RW1 arranged in different rows are the segmented walls FW, and four of the second reflective walls RW2 arranged in different columns are the segmented walls FW. Similarly, the widths W of all the gaps F may be approximately equal to each other, thereby absorbing the volumetric expansion of the main body 131a uniformly.

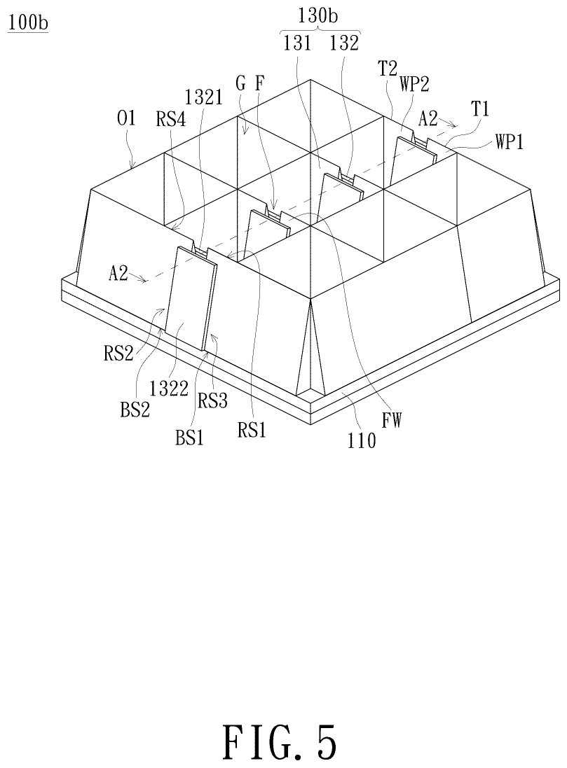

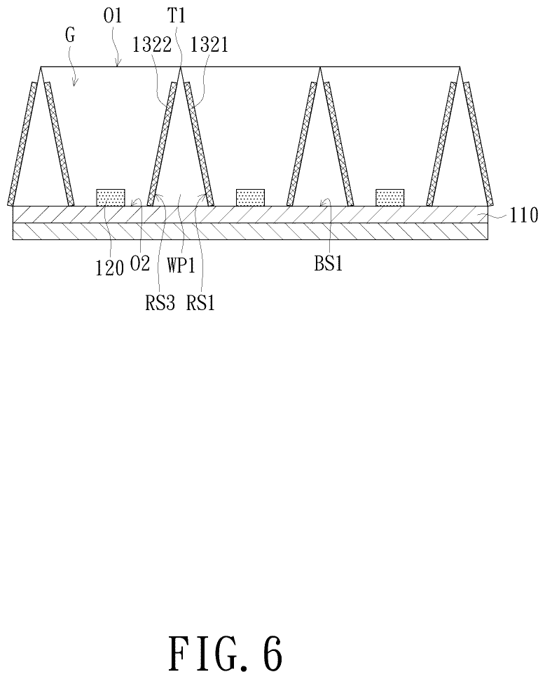

FIG. 5 is a schematic perspective view of a backlight module according to another embodiment of the disclosure. FIG. 6 is a schematic cross-sectional view of the backlight module, taken along line A2-A2 in FIG. 5. The structures and advantages of the backlight module 100b and the reflective structure 130b in the embodiment are similar to those of the embodiment shown in FIG. 1, and only the differences will be described below. Please refer to FIG. 5 and FIG. 6. The reflective structure 130b, for example, further includes a plurality of reflective sheets 132. The reflective sheets 132 are disposed between the first wall portions WP1 and the second wall portions WP2 of each of the segmented walls FW, respectively, such that more light beams emitted from the light emitting elements 120 may be reflected outward from the light source accommodating cavities G, thereby improving the light usage efficiency of the backlight module 100b. In the embodiment, each of the reflective sheets 132, for example, includes a first flexible reflective sheet 1321 and a second flexible reflective sheet 1322. In each of the segmented walls FW, the first flexible reflective sheet 1321 is fixed on the first reflective surface RS1 and the fourth reflective surface RS4, and the second flexible reflective sheet 1322 is fixed on the second reflective surface RS2 and the third reflective surface RS3.

Specifically, two opposite sides of the first flexible reflective sheet 1321 may be respectively adhered onto the first reflective surface RS1 and the fourth reflective surface RS4. A middle part of the first flexible reflective sheet 1321 is located between the first wall portion WP1 and the second wall portion WP2 and partially covers the gap F. Similarly, two opposite sides of the second flexible reflective sheet 1322 may be respectively adhered onto the second reflective surface RS2 and the third reflective surface RS3. A middle part of the second flexible reflective sheet 1322 is located between the first wall portion WP1 and the second wall portion WP2 and partially covers the gap F. In addition, the hardnesses of the first flexible reflective sheet 1321 and the second flexible reflective sheet 1322 are less than the hardness of the reflective structure 130b. Therefore, the first flexible reflective sheet 1321 and the second flexible reflective sheet 1322 are able to deform accordingly when compressed by the first wall portion WP1 and the second wall portion WP2, thereby preserving a tolerance for volumetric expansion of the first wall portion WP1 and the second wall portion WP2. In an embodiment, the first flexible reflective sheet 1321 and the second flexible reflective sheet 1322 may include a structure that facilitates folding. The structure includes, for example, pre-folding lines, perforation lines, or the like, thereby enabling the first flexible reflective sheet 1321 and the second flexible reflective sheet 1322 to deform more easily during the compression.

In the embodiment, each of the first wall portions WP1 further includes, for example, a first top T1 opposite to the first bottom surface BS1. Each of the second wall portions WP2 further includes a second top T2 opposite to the second bottom surface BS2. Each of the first flexible reflective sheets 1321 and each of the second flexible reflective sheets 1322 expose each of the first tops T1 and each of the second tops T2 and expose a portion of each of the gaps F adjacent to each of the first tops T1 and each of the second tops T2. Specifically, the light source accommodating cavities G may include a light emitting outlet O1 and a bottom opening O2, respectively. The light emitting outlet O1 is opposite to the bottom opening O2. The light emitting elements 120 are disposed on the bottom openings O2. In each of the segmented walls FW, the first top T1 and the second top T2 surround the light emitting outlet O1. Since the first flexible reflective sheets 1321 and the second flexible reflective sheets 1322 do not extend to the first tops T1 and the second tops T2, the amount of the light beams through the light emitting outlet O1 reflected by the first flexible reflective sheets 1321 and the second flexible reflective sheets 1322 can be reduced, enabling the light beams emitted from the light emitting elements 120 to pass above the first flexible reflective sheets 1321 and the second flexible reflective sheets 1322 (i.e., the side away from the substrate 110) more easily, thereby improving the uniformity of the light output. In addition, the first flexible reflective sheets 1321 and the second flexible reflective sheets 1322 may expose a portion of the gaps F adjacent to the first tops T1 and the second tops T2.

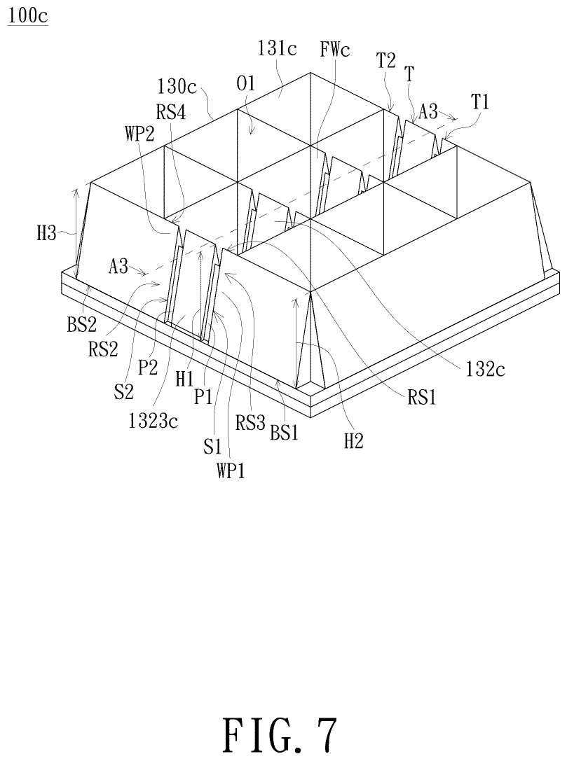

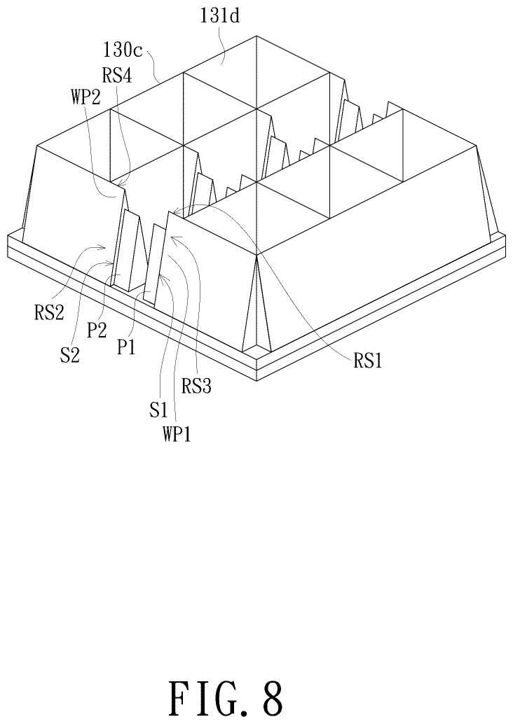

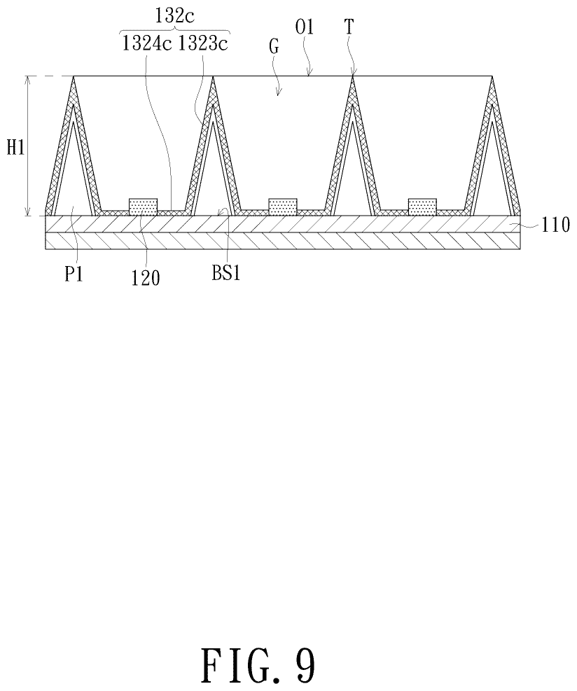

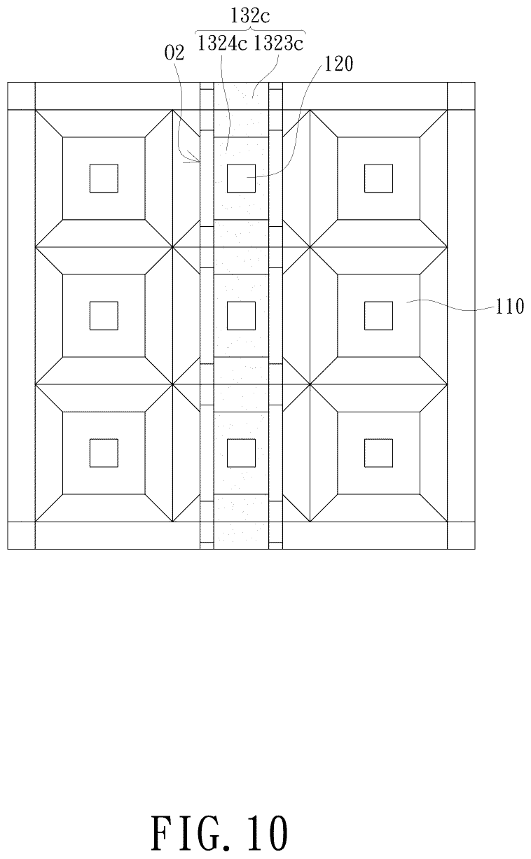

FIG. 7 is a schematic perspective view of a backlight module according to another embodiment of the disclosure. FIG. 8 is a schematic perspective view of the backlight module in FIG. 7 with the reflective sheets omitted. FIG. 9 is a schematic cross-sectional view of the backlight module, taken along line A3-A3 in FIG. 7. FIG. 10 is a schematic top view of the backlight module in FIG. 7. The structures and advantages of the backlight module 100c and the reflective structure 130c in the embodiment are similar to those of the embodiment shown in FIG. 5, and only the differences will be described below. Please refer to FIG. 7, FIG. 8, and FIG. 9. Each of the first wall portions WP1 of the main body 131c further includes a first positioning portion P1. The first positioning portion P1 protrudes from the first cut surface S1 and is recessed on the first reflective surface RS1 and the third reflective surface RS3. Each of the second wall portions WP2 further includes, for example, a second positioning portion P2. The second positioning portion P2 protrudes from the second cut surface S2 and is recessed on the second reflective surface RS2 and the fourth reflective surface RS4. Each of the reflective sheets 132 includes a bent portion 1323c corresponding to the first positioning portion P1 and the second positioning portion P2, respectively. In each of the segmented walls FWc, the bent portion 1323c covers the first positioning portion P1 and the second positioning portion P2 and is separated from the first positioning portion P1 and the second positioning portion P2. In the embodiment, the bent portion 1323c of the reflective sheet 132c, which is disposed between the first wall portion WP1 and the second wall portion WP2, covers the first positioning portion P1 and the second positioning portion P2 correspondingly but does not cover the first top T1 of the first wall portion WP1 or the second top T2 of the second wall portion WP2.

It should be noted that the bent portion 1323c illustrated in FIG. 9 is separated from the first positioning portion P1, and the position of the bent portion 1323c relative to the second positioning portion P2 is generally the same as the position of the bent portion 1323c relative to the first positioning portion P1. Accordingly, the backlight module 100c can enhance light usage efficiency via the bent portion 1323c and reserve sufficient room among the bent portion 1323c, the first wall portion WP1, and the second wall portion WP2 for the potential expansion of the first wall portion WP1 and the second wall portion WP2. Furthermore, the bent portion 1323c may also be separated from the first cut surface S1 and the second cut surface S2, meaning that the reflective sheet 132c may be separated from the first wall portion WP1 and the second wall portion WP2, thereby providing more room for the potential expansion of the first wall portion WP1 and the second wall portion WP2. The bent portion 1323c may have a shape complementary to the first positioning portion P1 and the second positioning portion P2 to facilitate alignment and mounting onto the first positioning portion P1 and the second positioning portion P2. For example, the first positioning portions P1 and the second positioning portions P2 may have a triangular prism shape, and the bent portion 1323c may be folded to form a recess complementary to the triangular prism.

Please refer to FIG. 7 and FIG. 9. Each of the bent portions 1323c includes a top T disposed between the first top T1 and the second top T2. A height H1 of each of the tops T relative to each of the first bottom surfaces BS1 is less than or equal to a height H2 of each of the first tops T1 relative to each of the first bottom surfaces BS1, and a height of each of the tops T relative to each of the second bottom surfaces BS2 (the same as the height H1) is less than or equal to a height H3 of each of the second tops T2 relative to each of the second bottom surfaces BS2. In the embodiment, the heights H1, H2, and H3, for example, are equal to each other. Therefore, it prevents the tops T from reflecting excessive light beams passing through the light emitting outlet O1 in comparison with the first tops T1 and the second tops T2, thereby improving the light output uniformity of the backlight module 100c.

Please refer to FIG. 9 and FIG. 10. In addition, each of the reflective sheets 132c further includes, for example, an extending portion 1324c. In each of the reflective sheets 132c, the extending portion 1324c is connected to the bent portion 1323c and covers the bottom opening O2 of the light source accommodating cavity G for enhancing the light usage efficiency. Specifically, the extending portion 1324c may cover the bottom opening O2 partially and is fixed on the substrate 110 through the bottom opening O2. In addition, the extending portion 1324c may include an avoidance hole aligned with the light emitting element 120.

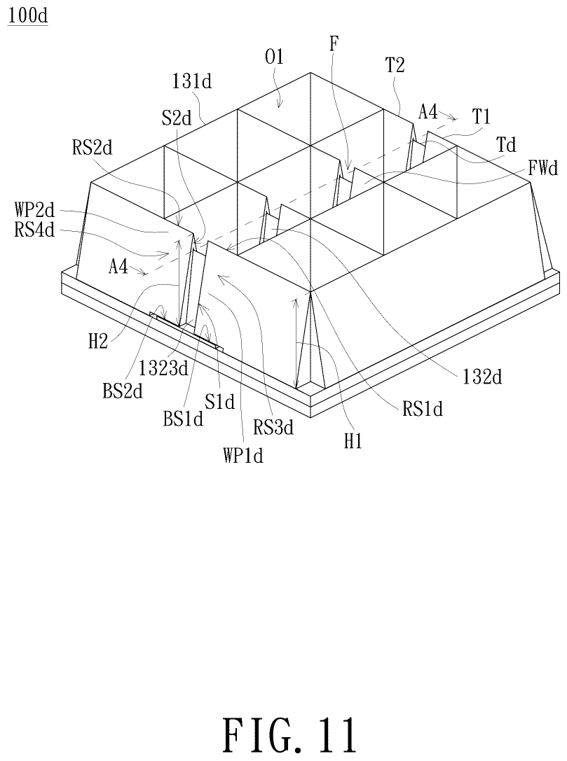

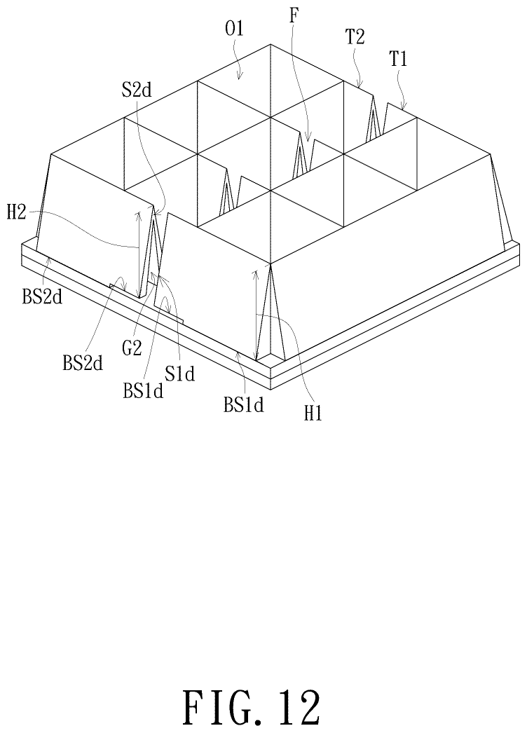

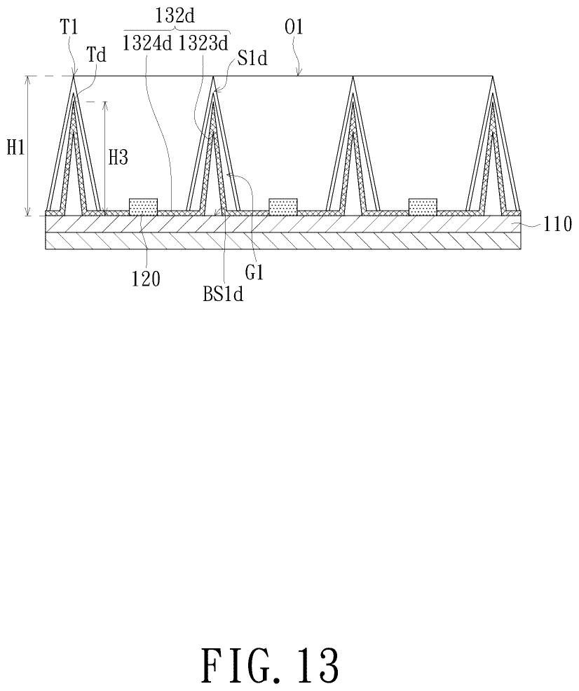

FIG. 11 is a schematic perspective view of a backlight module according to another embodiment of the disclosure. FIG. 12 is a schematic perspective view of the backlight module in FIG. 11 with the reflective sheets omitted. FIG. 13 is a schematic cross-sectional view of the backlight module, taken along line A4-A4 in FIG. 11. The structures and advantages of the backlight module 100d and the reflective structure 130d in the embodiment are similar to those of the embodiment shown in FIG. 5, and only the differences will be described below. Please refer to FIG. 11, FIG. 12, and FIG. 13. The first cut surface S1d may include a first positioning groove G1 (illustrated in FIG. 13), wherein the first positioning groove G1 is recessed into the first wall portion WP1d from the first cut surface S1d. The first positioning groove G1 does not extend to the first reflective surface RS1d and the third reflective surface RS3d but extends to the first bottom surface BS1d. The second cut surface S2d may include a second positioning groove G2 wherein the second positioning groove G2 is recessed into the second wall portion WP2d from the second cut surface S2d. The second positioning groove G2 does not extend to the second reflective surface RS2d and the fourth reflective surface RS4d but extends to the second bottom surface BS2d. The bent portion 1323d of the reflective sheet 132d is configured to correspond to the first positioning groove G1 and the second positioning groove G2, respectively. In each of the segmented walls FWd, the bent portion 1323d is disposed in the first positioning groove G1 and the second positioning groove G2 and is exposed between the first wall portion WP1d and the second wall portion WP2d. The bent portion 1323d is separated from the first wall portion WP1d and the second wall portion WP2d, respectively. Accordingly, the backlight module 100d may increase the light usage efficiency via the bent portion 1323d and preserve some room for the potential expansion of the first wall portion WP1d and the second wall portion WP2d. Specifically, the two opposite sides of the bent portion 1323d may respectively extend into the first positioning groove G1 and the second positioning groove G2 and be covered by the first wall portion WP1d and the second wall portion WP2d. The middle portion of the bent portion 1323d may be exposed between the first wall portion WP1d and the second wall portion WP2d and partially cover the gap F.

A height H3 of the top Td of each of the bent portions 1323d relative to each of the first bottom surfaces BS1d is less than a height H1 of each of the first tops T1 relative to each of the first bottom surfaces BS1d, and a height of each of the tops Td relative to each of the second bottom surfaces BS2d (the same as the height H3) is less than a height H2 of each of the second tops T2 relative to each of the second bottom surfaces BS2d. Accordingly, it prevents the tops Td from reflecting excessive light beams passing through the light emitting outlet O1 in comparison with the first tops T1 and the second tops T2, thereby improving the light output uniformity of the backlight module 100d. Similarly, the reflective sheets 132d may further enhance the light usage efficiency of the backlight module 100d through the extending portions 1324d. In another embodiment, the extending portion 1324d may be omitted from the reflective sheets 132d. Since the features of the extending portion 1324d are generally the same as those of the extending portion 1324c shown in FIG. 9 and FIG. 10, the related descriptions are omitted thereby. In addition, in the embodiment, the first bottom surface BS1d and the second bottom surface BS2d may include slits (illustrated in FIG. 11 and FIG. 12) to allow the extending portion 1324d to extend therethrough. The first positioning groove G1 and the second positioning groove G2 may be in communication with the corresponding slits.

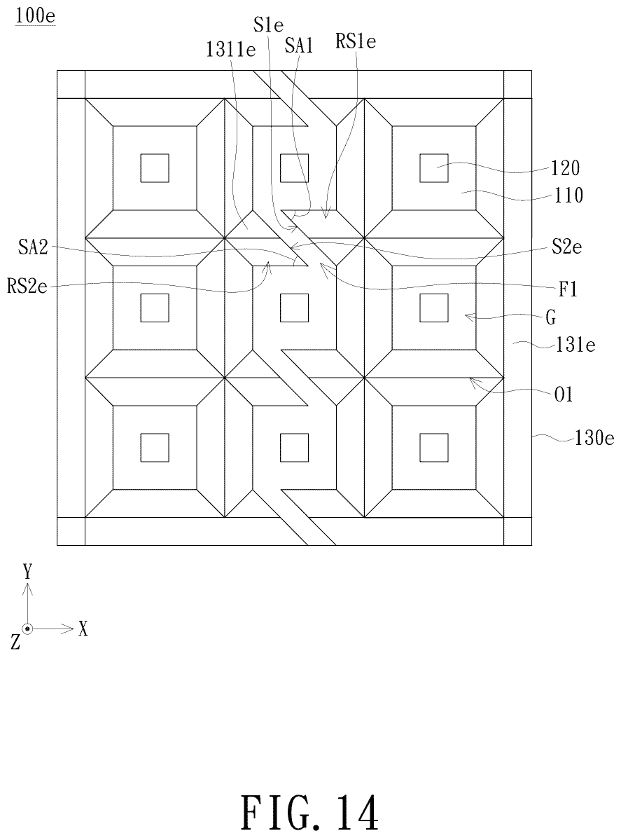

FIG. 14 is a schematic top view of the backlight module according to another embodiment of the disclosure. The structures and advantages of the backlight module 100e and the reflective structure 130e in the embodiment are similar to those of the embodiment shown in FIG. 1, and only the differences will be described below. Please refer to FIG. 14. Each of the first cut surfaces S1e and each of the first reflective surfaces RS1e define, for example, an acute angle SA1 therebetween, and each of the second cut surfaces S2e and each of the second reflective surfaces RS2e define, for example, an acute angle SA2 therebetween. In other words, the gap F1 may be inclined relative to the second direction Y and extend through the reflective wall 1311e. In this way, the first cut surface S1e and the second cut surface S2e may block more light beams from passing through the gap F1, allowing more light beams to pass through the light emitting outlet O1, thereby enhancing the light output uniformity of the light source accommodating cavities G. In the embodiment, the first cut surface S1e and the second cut surface S2e are, for example, substantially perpendicular to the XY-plane. Also, the first cut surface S1e and the second cut surface S2e are substantially parallel to each other, meaning that the acute angle SA1 is generally equal to the acute angle SA2. Similarly, the first cut surface S1e and the second cut surface S2e may be configured to provide a light-reflecting function. In one embodiment, the main body 131e of the reflective structure 130e provides a configuration including the reflective sheets 132 in FIG. 5, the reflective sheets 132c in FIG. 7, and the reflective sheets 132d in FIG. 11, thereby enhancing the light usage efficiency of the backlight module 100e.

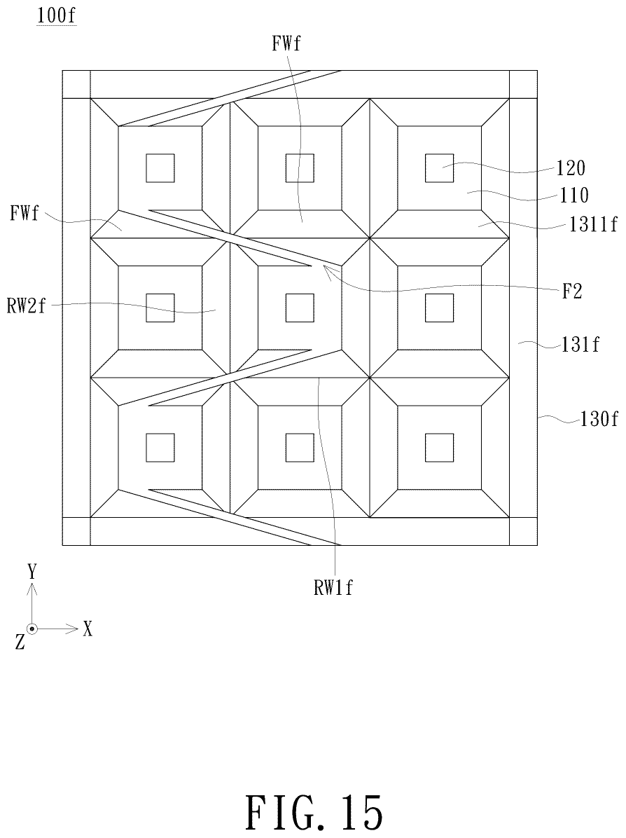

FIG. 15 is a schematic top view of the backlight module according to another embodiment of the disclosure. The structures and advantages of the backlight module 100f and the reflective structure 130f in the embodiment are similar to those of the embodiment shown in FIG. 1, and only the differences will be described below. Please refer to FIG. 15. The gap F2 further extends to one of the reflective walls 1311f adjacent to the segmented wall FWf and cuts through the corresponding reflective walls 1311f adjacent to the segmented wall FWf. In other words, the same gap F2 may cut through the two adjacent reflective walls 1311f arranged along one direction so as to form the two adjacent segmented walls FWf. In the embodiment, the gap F2 is, for example, inclined relative to the first direction X and the second direction Y and cuts through the two connected first reflective walls RW1f along the first direction X. In one embodiment, the gap F2 may cut through the two adjacent first reflective walls RW1f of the main body 131 arranged along the second direction Y or cut through the first reflective wall RW1f and the second reflective wall RW2f which are adjacent to each other. In the embodiment, the gap F2 may keep a constant width along the first direction X. Though the foregoing description uses the segmented wall FWf and the reflective wall 1311f adjacent to the segmented wall FWf as an example of the two adjacent reflective walls 1311f, the disclosure is not limited thereto. In another embodiment, one of the segmented walls FWf and the reflective walls 1311f adjacent to the segmented wall FWf (e.g., two reflective walls 1311f on two sides of the segmented wall FWf) may be divided by the same gap F2. In other words, the gap F2 may cut through three or more of the reflective walls 1311f adjacent to each other. Similarly, the main body 131f may provide a configuration including the reflective sheets 132 shown in FIG. 5, the reflective sheets 132c shown in FIG. 7, and the reflective sheets 132d shown in FIG. 11, thereby enhancing the light usage efficiency.

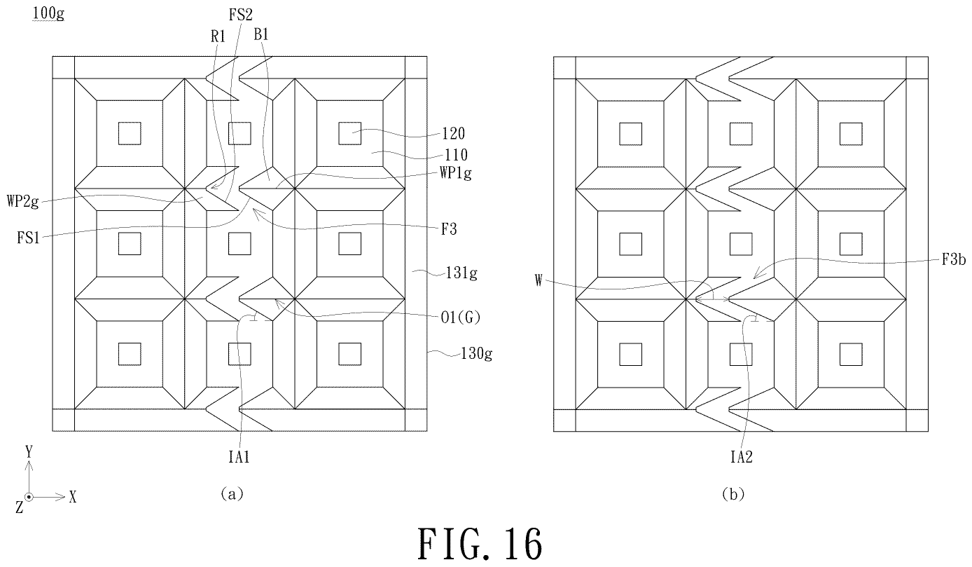

FIG. 16 is a schematic top view of the backlight module according to another embodiment of the disclosure where (a) and (b) in FIG. 16 show two different implementations. The structures and advantages of the backlight module 100g and the reflective structure 130g in the embodiment are similar to those of the embodiment shown in FIG. 1, and only the differences will be described below. Please refer to the implementation (a) in FIG. 16. In the main body 131g, each of the first wall portions WP1g may include a first cut side FS1, and each of the second wall portions WP2g may include a second cut side FS2. Each of the first cut sides FS1 and each of the second cut sides FS2 face towards each other and are separated from each other. Each of the first cut sides FS1 includes a first light blocking portion B1 protruded towards each of the second cut sides FS2. Each of the second cut sides FS2 includes a first recess portion R1 structurally complementary to each of the first light blocking portions B1. In this manner, the first cut sides FS1 and the second cut sides FS2 are able to block more light beams from passing through the gap F3, allowing more light beams to emit from the light emitting outlet O1, thereby improving the light output uniformity of all the light source accommodating cavities G. In addition, the first cut sides FS1 and the second cut sides FS2 may be configured to provide a light-reflecting function, thereby improving the light usage efficiency. In the embodiment, the first light blocking portion B1 has a shape that is generally as a triangular prism. The first recess portion R1 has a shape complementary to the triangular prism. Similarly, the gap F3 may maintain a constant width along the first direction X. The first light blocking portion B1 and the first recess portion R1 may be formed by cutting or formed monolithically.

Incidentally, by adjusting the angle IA1 between the gap F3 and the first direction X, the light blocking effectiveness of the first light blocking portion B1 may be changed. For example, referring to the implementation (b) shown in FIG. 16, the angle IA2 between the gap F3b and the first direction X is smaller than the angle IA1 in implementation (a), and the gap F3b still maintains a constant width along the first direction X. In one embodiment, the width W of the gap F3b may be approximately between 0.5 mm and 1.5 mm, and the angle IA2 may be between 9 degrees and 37 degrees. The disclosure is not limited thereto.

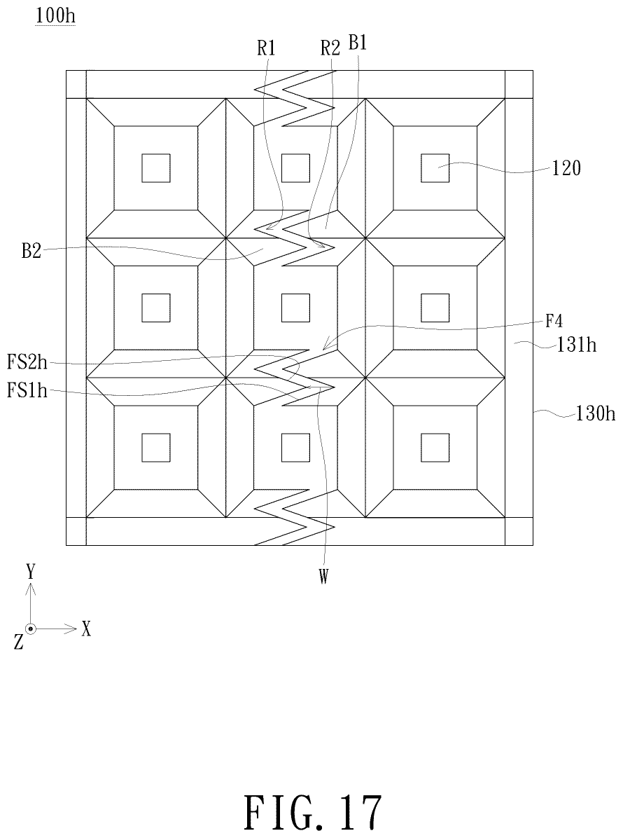

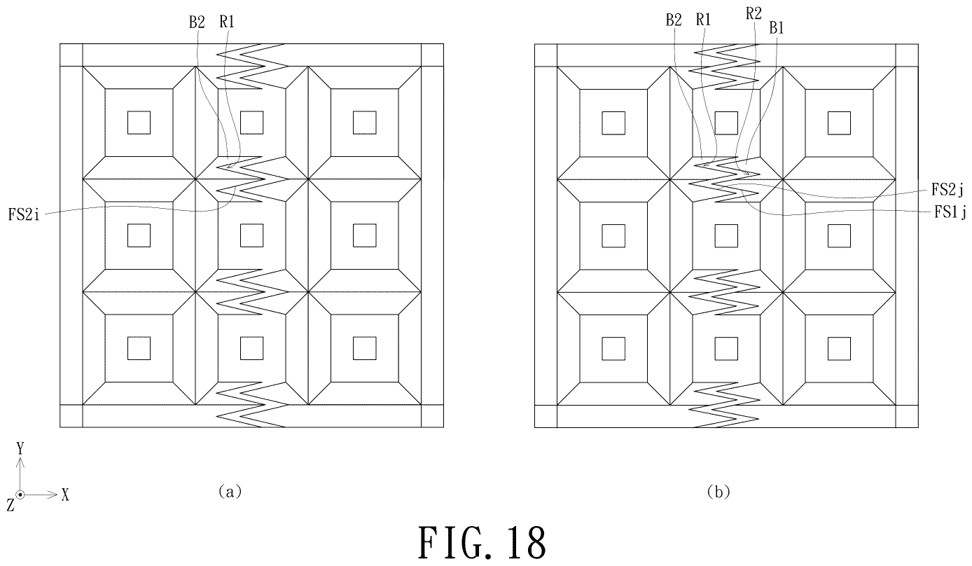

FIG. 17 is a schematic top view of the backlight module according to another embodiment of the disclosure. FIG. 18 is a schematic top view of the backlight module according to another embodiment of the disclosure. Two different implementations are illustrated as (a) and (b) in FIG. 18. The structures and advantages of the backlight module 100h and the reflective structure 130h in the embodiment are similar to those of the embodiment shown in FIG. 16, and only the differences will be described below. Please refer to FIG. 17. In the main body 131h, each of the second cut sides FS2h further includes, for example, a second light blocking portion B2. Each of the second light blocking portions B2 protrudes towards each of the first cut sides FS1h. Each of the first cut sides FS1h further includes a second recess portion R2 complementary to the corresponding second light blocking portion B2, such that the first cut sides FS1h and the second cut sides FS2h may block more light through the gaps F4. Similarly, the gap F4 may maintain a constant width along the first direction X. The second light blocking portion B2 has a shape which is generally a triangular prism. The first recess portion R1 has a shape complemantary to the aforementioned triangular prism, and the gap F4 has a jagged shape accordingly. Also, as the quantity of the first light blocking portions B1 and the second light blocking portions B2 increases, the light-blocking effectiveness may be enhanced. Accordingly, as the width W of the gap F4 increases, a greater number of the first light blocking portions B1 and the second light blocking portions B2 may be disposed to provide a better light blocking effect.

For example, in the embodiment, the first cut side FS1h may include two first light blocking portions B1 and one second recess portion R2 disposed between the two first light blocking portions B1. The second cut side FS2h may include two second light blocking portions B2 and one first recess portion R1. However, the quantity of the second light blocking portion B2 and the quantity of the second recess portion R2 are not limited. For example, referring to the implementation (a) in FIG. 18, the second cut side FS2i may include three second light blocking portions B2 and two first recess portions R1. The implementation (b) in FIG. 18 shows that the first cut side FS1j includes three first light blocking portions B1 and two second recess portions R2. The second cut side FS2j includes three second light blocking portions B2 and two first recess portions R1.

In summary, in the present disclosure, the main body of the reflective structure includes a plurality of reflective walls. The reflective walls include a plurality of segmented walls. The main body is divided into the first portion and the second portion separated from each other by the gaps of the segmented walls. In this manner, when the ambient temperature increases, the first portion and the second portion separated from each other may absorb the volumetric expansion of the main body, thereby preventing significant dimensional changes of the main body due to the increased ambient temperature. Based on the foregoing, the disclosure is capable of reducing the dimensional variation of the reflective structure when the ambient temperature increases. Since the backlight module of the present disclosure adopts the aforementioned reflective structure, when the ambient temperature increases, the difference of dimensional changes among the reflective structure and other components can be reduced, thereby preventing deformation of the backlight module due to excessive dimensional mismatch. Accordingly, the disclosure enhances the durability of the backlight module.

The foregoing description of the preferred embodiments of the disclosure has been presented for purposes of illustration and description. It is not intended to be exhaustive or to limit the disclosure to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the disclosure and its best mode practical application, thereby to enable persons skilled in the art to understand the disclosure for various embodiments and with various modifications as are suited to the particular use or implementation contemplated. It is intended that the scope of the disclosure be defined by the claims appended hereto and their equivalents in which all terms are meant in their broadest reasonable sense unless otherwise indicated. Therefore, the term “the disclosure”, “the present disclosure” or the like does not necessarily limit the claim scope to a specific embodiment, and the reference to particularly preferred exemplary embodiments of the disclosure does not imply a limitation on the disclosure, and no such limitation is to be inferred. The disclosure is limited only by the spirit and scope of the appended claims. The use of “at least one of . . . and . . . ” thereof herein may include “one or more of the items contained in the list”. For example, the use of “at least one of A and B” thereof herein may include only A, or only B, or A and B. Similarly, the use of “at least one of A, B, and C” thereof herein may include only A, or only B, or only C, or any combination of A, B, and C. Moreover, these claims may refer to use “first”, “second”, etc. following with noun or element. Such terms should be understood as a nomenclature and should not be construed as giving the limitation on the number of the elements modified by such nomenclature unless specific number has been given. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the disclosure. It should be appreciated that variations may be made in the embodiments described by persons skilled in the art without departing from the scope of the present disclosure as defined by the following claims. Moreover, no element and component in the present disclosure is intended to be dedicated to the public regardless of whether the element or component is explicitly recited in the following claims.

What is claimed is:

1. A reflective structure, comprising:
a main body, comprising a plurality of light source accommodating cavities and a plurality of reflective walls, wherein the plurality of reflective walls surround the plurality of light source accommodating cavities respectively, the plurality of reflective walls comprise a plurality of segmented walls, and each of the plurality of segmented walls has a first wall portion and a second wall portion separated from each other;
wherein the main body is divided into a first portion and a second portion separated from each other via the plurality of segmented walls.

2. The reflective structure according to claim 1, wherein each of the first wall portions comprises a first cut surface, a first reflective surface, and a first bottom surface, and the first cut surface and the first reflective surface are connected with each other and stand on the first bottom surface,
each of the second wall portions comprises a second cut surface, a second reflective surface, and a second bottom surface, the second cut surface faces the first cut surface and stands on the second bottom surface, the second reflective surface is connected to the second cut surface and stands on the second bottom surface, and each of the first reflective surfaces is disposed on one side of each of the segmented walls, and each of the second reflective surfaces is disposed on another side opposite to the one side of each of the segmented walls.

3. The reflective structure according to claim 2, wherein each of the first cut surfaces is substantially perpendicular to each of the first reflective surfaces, and each of the second cut surfaces is substantially perpendicular to each of the second reflective surfaces.

4. The reflective structure according to claim 2, wherein each of the first cut surfaces and each of the first reflective surfaces define an acute angle therebetween, and each of the second cut surfaces and each of the second reflective surfaces define an acute angle therebetween.

5. The reflective structure according to claim 2, further comprising a plurality of reflective sheets, wherein the plurality of reflective sheets are disposed between each of the first wall portions and each of the second wall portions, respectively.

6. The reflective structure according to claim 5, wherein each of the first wall portions further comprises a third reflective surface opposite to the first reflective surface, each of the second wall portions further comprises a fourth reflective surface opposite to the second reflective surface, each of the reflective sheets comprises a first flexible reflective sheet and a second flexible reflective sheet, the first flexible reflective sheet is fixed on the first reflective surface and the fourth reflective surface, and the second flexible reflective sheet is fixed on the second reflective surface and the third reflective surface.

7. The reflective structure according to claim 6, wherein each of the first wall portions further comprises a first top opposite to the first bottom surface, each of the second wall portions further comprises a second top opposite to the second bottom surface, and each of the first tops and each of the second tops are exposed from each of the first flexible reflective sheets and each of the second flexible reflective sheet.

8. The reflective structure according to claim 5, wherein:
each of the first wall portions further comprises a third reflective surface and a first positioning portion, the third reflective surface is opposite to the first reflective surface, and the first positioning portion protrudes from the first cut surface and is recessed on the first reflective surface and the third reflective surface;
each of the second wall portions further comprises a fourth reflective surface and a second positioning portion, the fourth reflective surface is opposite to the second reflective surface, and the second positioning portion protrudes from the second cut surface and is recessed on the second reflective surface and the fourth reflective surface; and
each of the reflective sheets comprises a bent portion corresponding to each of the first positioning portions and each of the second positioning portions, and each of the bent portions covers the corresponding first positioning portion and the corresponding second positioning portion and is separated from the corresponding first positioning portions and the corresponding second positioning portions.

9. The reflective structure according to claim 8, wherein each of the first wall portions further comprises a first top opposite to the first bottom surface, each of the second wall portions further comprises a second top opposite to the second bottom surface, each of the bent portions comprises a top disposed between the first top and the second top, a height of each of the tops relative to each of the first bottom surfaces is less than or equal to a height of each of the first tops relative to each of the first bottom surfaces, and a height of each of the tops relative to each of the second bottom surfaces is less than or equal to a height of each of the second tops relative to each of the second bottom surfaces.

10. The reflective structure according to claim 5, wherein each of the first cut surfaces comprises a first positioning groove extending to the first bottom surface, each of the second cut surfaces comprises a second positioning groove extending to the second bottom surface, each of the reflective sheets comprises a bent portion corresponding to each of the first positioning grooves and each of the second positioning grooves, each of the bent portions is disposed in the corresponding first positioning groove and the corresponding second positioning groove and is exposed between the corresponding first positioning groove and the corresponding second positioning groove, and the bent portions are separated from each of the first wall portions having the corresponding first positioning groove and each of the second wall portions having the corresponding second positioning groove.

11. The reflective structure according to claim 10, wherein each of the first wall portions further comprises a first top opposite to the first bottom surface, each of the second wall portions further comprises a second top opposite to the second bottom surface, each of the bent portions comprises a top disposed between the first top and the second top, a height of each of the tops relative to each of the first bottom surfaces is less than a height of each of the first tops relative to each of the first bottom surfaces, and a height of each of the tops relative to each of the second bottom surfaces is less than a height of each of the second tops relative to each of the second bottom surfaces.

12. The reflective structure according to claim 5, wherein each of the light source accommodating cavities comprises a light emitting outlet and a bottom opening opposite to each other, each of the reflective sheets is separated from each of the first wall portions and each of the second wall portions, each of the reflective sheets comprises a bent portion and an extending portion, the bent portions are disposed between each of the first wall portions and each of the second wall portions respectively, and the extending portions are connected to the bent portions and cover the bottom openings respectively.

13. The reflective structure according to claim 2, wherein the first wall portion and the second wall portion separated from each other collectively form a gap at a location of the segmented wall, and each of the gaps further extends to at least one of the reflective walls adjacent to the plurality of segmented walls.

14. The reflective structure according to claim 1, wherein each of the first wall portions comprises a first cut side, each of the second wall portions comprises a second cut side, each of the first cut sides and each of the second cut sides face each other and are separated from each other, each of the first cut sides comprises a first light blocking portion protruding toward each of the second cut sides, and each of the second cut sides comprises a first recess portion structurally complementary to each of the first light blocking portions.

15. The reflective structure according to claim 14, wherein each of the second cut sides further comprises a second light blocking portion protruding toward each of the first cut sides, and each of the first cut sides further comprises a second recess portion structurally complementary to each of the second light blocking portions.

16. The reflective structure according to claim 1, wherein the plurality of reflective walls further comprise a plurality of first reflective walls and a plurality of second reflective walls, the plurality of first reflective walls are connected to each other and extend along a first direction, the plurality of second reflective walls are connected to each other and extend along a second direction different from the first direction, at least one of the first reflective walls comprises the segmented wall, and at least one of the second reflective walls comprises the segmented wall.

17. The reflective structure according to claim 1, wherein the plurality of reflective walls further comprise a plurality of first reflective walls and a plurality of second reflective walls, the plurality of first reflective walls are connected to each other and extend along a first direction, the plurality of second reflective walls are connected to each other and extend along a second direction different from the first direction, and more than one of the plurality of first reflective walls comprise the segmented wall, or more than one of the plurality of second reflective walls comprise the segmented wall.

18. The reflective structure according to claim 1, wherein each of the first wall portions comprises a first cut surface, each of the first cut surfaces faces each of the second wall portions, each of the second wall portions comprises a second cut surface, each of the second cut surfaces faces each of the first cut surfaces, and each of the first cut surfaces is substantially parallel to each of the second cut surfaces.

19. A backlight module, comprising:
a substrate;
a plurality of light emitting elements, disposed on a surface of the substrate; and
a reflective structure, disposed on the surface, wherein the reflective structure comprises a main body, the main body comprises a plurality of light source accommodating cavities and a plurality of reflective walls surrounding the plurality of light source accommodating cavities respectively, the plurality of reflective walls comprise a plurality of segmented walls, each of plurality of the segmented walls comprises a first wall portion and a second wall portion separated from each other, and the main body is divided to a first portion and a second portion separated from each other through the segmented walls.
